(19) United States
(12) Patent Application Publication
(10) Pub. No.: US 2014/0353004 A1
(43) Pub. Date: Dec. 4, 2014

(54) INSULATION RESIN COMPOSITION FOR PRINTED CIRCUIT BOARD HAVING IMPROVED THERMAL CONDUCTIVITY AND ELECTRICAL PROPERTIES, INSULATING FILM, PREPREG AND PRINTED CIRCUIT BOARD

(71) Applicant: SAMSUNG ELECTRO-MECHANICS CO., LTD., Suwon-Si (KR)

(72) Inventors: Hyun Chul Jung, Suwon-Si (KR); Joon Seok Kang, Suwon-Si (KR); Jang Bae Son, Suwon-Si (KR); Sang Hyun Shin, Suwon-Si (KR); Kwang Jik Lee, Suwon-Si (KR); Hye Sook Shin, Suwon-Si (KR)

(73) Assignee: SAMSUNG ELECTRO-MECHANICS CO., LTD., Suwon-Si (KR)

(21) Appl. No.: 14/270,131

(22) Filed: May 5, 2014

(30) Foreign Application Priority Data
May 30, 2013 (KR) 10-2013-0061748

(51) Int. Cl. H05K 1/03; B05D 3/00; C08K 3/22; C08K 3/38; C08K 3/36

(52) U.S. Cl. CPC H05K 1/0373; C08K 3/38; C08K 3/36; C08K 3/22; B05D 3/007; C08K 2003/385; H05K 2201/0209; C08K 2003/2227; C08K 2201/001; C08K 2201/003
USPC 174/250; 523/400; 523/445; 523/457; 427/372.2

(57) ABSTRACT

Disclosed herein are an insulation resin composition for a printed circuit board including: an epoxy resin, a first inorganic filler having thermal conductivity of 20 W/mK or more, and a second inorganic filler having relative permittivity less than 10, and an insulating film, a prepreg, and a printed circuit board.

### CROSS REFERENCE TO RELATED APPLICATION

This application claims the benefit of Korean Patent Application No. 10-2013-0061748, filed on May 30, 2013, entitled “Insulation Resin Composition for Printed Circuit Board Having Improved Thermal Conductivity and Electrical Properties, Insulating Film, Prepreg, and Printed Circuit Board”, which is hereby incorporated by reference in its entirety into this application.

### BACKGROUND OF THE INVENTION

1. Technical Field

The present invention relates to an insulation resin composition for a printed circuit board having improved thermal conductivity and electrical properties, an insulating film, a prepreg, and a printed circuit board.

2. Description of the Related Art

In accordance with the trend of high performance and slimness and lightness of an electronic device, a heat generation amount has been increased. In addition, according to energy conservation, appearance of renewable energy and demand of an energy efficiency increase, a high power device having a high voltage has been increasingly used, and in particular, heat generation in the high power device significantly affects safety and life span of the device. Therefore, necessity of a heat radiation substrate capable of effectively delivering heat generated in the device inside and outside has been increased.

The existing substrate generally uses an epoxy-based polymer resin as an insulating layer. Since the epoxy resin has improved insulating properties, strength, and thermal resistant properties, but low thermal conductivity, heat generated in the device connected to the substrate is not effectively delivered. Accordingly, a heat radiation substrate increases thermal conductivity by containing an inorganic filler having improved thermal conductivity into a resin such as an epoxy resin, or the like. Since the thermal conductivity of a composite material in the heat radiation substrate is increased depending on a content of the inorganic filler having improved thermal conductivity contained in the insulating layer, an attempt to contain the inorganic filler as much as possible into the resin has been mainly conducted. A currently and widely used heat radiating inorganic filler is an alumina (Al₂O₃), and 80 wt % or more is used in a resin composition in order to implement high thermal conductivity.

However, since the alumina (Al₂O₃) has a higher relative permittivity as compared to silica (SiO₂) widely used as an inorganic filler in a general printed circuit board, the consequently manufactured insulating film is not appropriate for being used in high speed and high frequency substrate. In addition, since the alumina has high hardness, when a large amount of the alumina is contained in a printed circuit board in order to implement high thermal conductivity, a problem that a drilling process is difficult occurs.

Meanwhile, Patent Document 1 discloses an epoxy resin composition containing an inorganic filler having thermal conductivity; however, fails to disclose an inorganic filler improving relative permittivity and breakdown voltage, and a specific method for implementing a low dielectric loss.

### PRIOR ART DOCUMENT

### Patent Document

Patent Document 1 Korean Patent Registration No. KR 10-01138060

### SUMMARY OF THE INVENTION

The present inventors found that a product manufactured by using an insulation resin composition for a printed circuit board including an epoxy resin, a first inorganic filler having thermal conductivity of 20 W/mK or more and an average particle diameter of 1 to 200 μm, and a second inorganic filler having relative permittivity less than 10 and an average particle diameter of 0.01 to 1 μm had high thermal conductivity and low relative permittivity, thereby completing the present invention.

Therefore, the present invention has been made in an effort to provide an insulation resin composition for a printed circuit board having high thermal conductivity and low relative permittivity.

In addition, the present invention has been made in an effort to provide an insulating film having high thermal conductivity and low relative permittivity manufactured from the insulation resin composition.

Further, the present invention has been made in an effort to provide a prepreg manufactured by impregnating an organic fiber or an inorganic fiber into the insulation resin composition.

In addition, the present invention has been made in an effort to provide a printed circuit board provided with the insulating film or the prepreg.

According to a preferred embodiment of the present invention, there is provided an insulation resin composition for a printed circuit board including: an epoxy resin; a first inorganic filler having thermal conductivity of 20 W/mK or more and an average particle diameter of 1 to 200 μm; and a second inorganic filler having relative permittivity less than 10 and an average particle diameter of 0.01 to 1 μm.

The first inorganic filler may have an average particle diameter of 1 to 70 μm and the second inorganic filler may have an average particle diameter of 0.05 to 1 μm.

The epoxy resin may be at least one selected from a group consisting of a bisphenol A type epoxy resin, a bisphenol F type epoxy resin, a phenol novolac epoxy resin, an o-cresol novolac epoxy resin, a naphthalene-based epoxy resin, a binaphthyl type epoxy resin, an anthracene type epoxy resin, a rubber modified type epoxy resin and a cycloaliphatic type epoxy resin.

The first inorganic filler may be at least one selected from a group consisting of alumina (Al₂O₃), boron nitride (BN), aluminum nitride (AlN), silicon carbide (SiC), beryllium oxide (BeO), beryllium hydroxide (Be(OH)₂), beryllium carbide (Be₂C) and magnesium oxide (MgO).

The second inorganic filler may be at least one selected from a group consisting of silica (SiO₂), boron nitride (BN), aluminum nitride (AlN), aluminum boride (AlBr₃), and aluminum fluoride (AlF₃).

The epoxy resin may be contained in 5 to 50 wt %, the first inorganic filler may be contained in 25 to 85.5 wt %, and the second inorganic filler may be contained in 5 to 47.5 wt %.

The insulation resin composition for a printed circuit board may further include 0.1 to 1 part by weight of at least one curing agent selected from a group consisting of an amine-based curing agent, an acid anhydride-based curing agent, a polyamine curing agent, a polysulfide curing agent, a phenolic novolac type curing agent, a bisphenol A type curing agent and a dicyandiamide curing agent based on 100 parts by weight of the insulation resin composition.

The insulation resin composition for a printed circuit board may further include 0.01 to 0.1 part by weight of a tertiary amine-based and an imidazole-based curing accelerator based on 100 parts by weight of the insulation resin composition.

According to another preferred embodiment of the present invention, there is provided an insulating film manufactured by coating and semi-curing the insulation resin composition as described above on a substrate.

According to another preferred embodiment of the present invention, there is provided a prepreg manufactured by impregnating and drying an organic fiber or an inorganic fiber into a varnish containing the insulation resin composition as described above.

According to another preferred embodiment of the present invention, there is provided a printed circuit board manufactured by stacking and laminating the insulating film as described above on a substrate having circuit patterns formed thereon.

According to another preferred embodiment of the present invention, there is provided a printed circuit board manufactured by stacking and laminating the prepreg as described above on a substrate having circuit patterns formed thereon.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view showing a general printed circuit board to which an insulation resin composition according to the present invention is applicable.

### DESCRIPTION OF THE PREFERRED EMBODIMENTS

Before the present invention is described in more detail, it must be noted that the terms and words used in the present specification and claims should not be interpreted as being limited to typical meanings or dictionary definitions, but should be interpreted as having meanings and concepts relevant to the technical scope of the present invention based on the rule according to which an inventor can appropriately define a concept implied by a term to best describe the method he or she knows for carrying out the invention. Further, the embodiments of the present invention are merely illustrative, and are not to be construed to limit the scope of the present invention, and thus there may be a variety of equivalents and modifications able to substitute for them at the point of time of the present application.

In the following description, it is to be noted that embodiments of the present invention are described in detail so that the present invention may be easily performed by those skilled in the art, and also that, when known techniques related to the present invention may make the gist of the present invention unclear, a detailed description thereof will be omitted.

Epoxy Resin

An insulation resin composition according to the present invention contains an epoxy resin in order to increase handling as an adhesion film of the resin composition after being dried. The epoxy resin has one or more epoxy groups included in a molecule, preferably, two or more epoxy groups included in a molecule, and more preferably, four or more epoxy groups included in a molecule, but the present invention is not specifically limited thereto.

Examples of the epoxy resin include a bisphenol A type epoxy resin, a bisphenol F type epoxy resin, a phenol novolac epoxy resin, an o-cresol novolac epoxy resin, a naphthalene-based epoxy resin, a binaphthyl type epoxy resin, an anthracene type epoxy resin, a rubber modified type epoxy resin and a cycloaliphatic type epoxy resin, but the present invention is not specifically limited thereto, wherein the epoxy resin is preferably a bisphenol A type epoxy resin, a bisphenol F type epoxy resin, and an o-cresol novolac epoxy resin. One kind of the epoxy resin may be used or a combination of two or more kinds thereof may be used.

A used content of the epoxy resin is preferably 5 to 50wt %, wherein in a case where the used content is less than 5wt %, handling is deteriorated, and in a case where the used content is more than 50wt %, an added content of other components is relatively decreased, such that there is little improvement in thermal conductivity and relative permittivity.

Rather than the above described epoxy resins, an acrylate-based resin, a polyimide resin, a urethane resin, a silicon resin, and a rubber resin capable of being UV-cured nay be used in the present invention.

Inorganic Filler

The insulation resin composition according to the present invention contains an inorganic filler in order to improve thermal conductivity and relative permittivity of the epoxy resin. The inorganic filler consists of a first inorganic filler for implementing high thermal conductivity and a second inorganic filler for implementing low relative permittivity and high breakdown voltage.

The first inorganic filler is at least one selected from a group consisting of alumina (Al₂O₃), boron nitride (BN), aluminum nitride (AlN), silicon carbide (SiC), beryllium oxide (BeO), beryllium hydroxide (Be(OH)₂), beryllium carbide (Be₂C) and magnesium oxide (MgO). In general, heat transfer in the inorganic filler is disturbed due to a phonon scattering phenomenon on an interface thereof, and in order to effectively perform the heat transfer, it is advantageous to minimize an interface between fillers by using an inorganic filler having a large particle size. Therefore, the first inorganic filler, which is a filler having thermal conductivity of 20 W/mK or more and little or low electrical conductivity, has an average particle diameter of 1 to 200 μm, preferably, 1 to 70 μm.

The second inorganic filler is at least one selected from a group consisting of silica (SiO₂), boron nitride (BN), aluminum nitride (AlN), aluminum boride (AlBr₃), and aluminum fluoride (AlF₃). A fine inorganic filler having a submicron size has an effect of improving breakdown voltage. Therefore, an effect of improving relative permittivity and an effect of improving breakdown voltage may be simultaneously expected by using the inorganic filler having a size of 1 μm or less. The second inorganic filler has a relative permittivity less than 10 and an average particle diameter of 0.01 to 1 μm, preferably, 0.05 to 1 μm.

Based on the insulation resin composition, the first inorganic filler is preferably used in 25 to 85.5 wt %, and the second inorganic filler is preferably used in 5 to 47.5 wt %.

In a case where a used content of the first inorganic filler is less than 25 wt %, thermal conductivity tends to be deteriorated and in a case where the used content thereof is more than 85.5 wt %, the second inorganic filler has a limited added content, such that electrical properties tend to be deteriorated. In addition, in a case where a used content of the second inorganic filler is less than 5 wt %, relative permittivity and breakdown voltage properties may be deteriorated and in a case where the used content of the second inorganic filler is more than 47.5 wt %, an efficiency of thermal conductivity may be decreased.

A ratio between the first and second inorganic fillers may be changed depending on a ratio of an average particle diameter, and a size of the first inorganic filler should be larger than that of the second inorganic filler. The first and second inorganic fillers may be used by combining two or more kinds thereof, respectively, and may be used by combining the first and second inorganic fillers having different sizes of each kind.

Curing Agent

Meanwhile, the present invention selectively uses a curing agent, wherein any general curing agent may be used as long as the curing agent includes a reacting group which is capable of reacting with an epoxide ring included in the epoxy resin, but the present invention is not specifically limited thereto.

More specifically, examples of the curing agents may include an amine-based curing agent, an acid anhydride-based curing agent, a polyamine curing agent, a polysulfide curing agent, a phenolic novolac type curing agent, a bisphenol A type curing agent and a dicyandiamide curing agent, and one kind or a combination of two or more kinds of curing agent may be used. A used content of the curing agent may be appropriately selected in consideration of a curing rate without deteriorating unique physical properties of the epoxy resin in the range of 0.1 to 1 parts by weight based on 100 parts by weight of the insulation resin composition.

Curing Accelerator

The insulation resin composition according to the present invention may be effectively cured by selectively containing a curing accelerator therein. Examples of the curing accelerator used in the present invention may include a tertiary amine-based curing accelerator, an imidazole-based curing accelerator, and the like, and the curing accelerator may be added in 0.01 to 0.1 part by weight based on 100 parts by weight of the insulation resin composition.

Examples of the amine-based curing accelerator may include trialkylamines such as triethylamine, tributylamine, and the like, and amine compounds such as 4-dimethylaminopyridine, benzyldimethylamine, 2,4,6-tris(dimethylaminomethyl)phenol, 1,8-diazabicyclo(5,4,0)-undecene (hereinafter, referred to as DBU), and the like, but the present invention is not specifically limited thereto. One kind or a combination of two or more kinds of amine-based curing accelerator may be used.

Examples of the imidazole-based curing accelerator may include imidazole compounds such as 2-methylimidazole, 2-undecylimidazole, 2-heptadecylimidazole, 1,2-dimethylimidazole, 2-ethyl-4-methylimidazole, 1,2-dimethylimidazole, 2-ethyl-4-methylimidazole, 2-phenylimidazole, 2-phenyl-4-methylimidazole, 1-benzyl-2-methylimidazole, 1-benzyl-2-phenylimidazole, 1-cyanoethyl-2-methylimidazole, 1-cyanoethyl-2-undecylimidazole, 1-cyanoethyl-2-ethyl-4-methylimidazole, 1-cyanoethyl-2-phenylimidazole, 1-cyanoethyl-2-undecylimidazoliumtrimellitate, 1-cyanoethyl-2-phenylimidazoliumtrimellitate, 2,4-diamino-6-[2′-methylimidazolyl-(1′)]-ethyl-s-triazine, 2,4-diamino-6-[2′-undecylimidazoly-(1′)]-ethyl-s-triazine, 2,4-diamino-6-[2′-ethyl-4′-methylimidazoly-(1′)]-ethyl-s-triazine, 2,4-diamino-6-[2′-methylimidazolyl-(1′)]-ethyl-s-triazineisocyanic acid adduct, 2-phenyl-imidazoleisocyanic acid adduct, 2-phenyl-4,5-dihydroxymethylimidazole, 2-phenyl-4-methyl-5-hydroxymethylimidazole, 2,3-dihydroxy-1H-pyroro[1,2-a]benzimidazole, 1-dodecyl-2-methyl-3-benzyl-imidazoliumchloride, 2-methylimidazoline, and 2-phenyl-imidazoline, and adducts of the imidazole compounds and the epoxy resin. One kind or a combination of two or more kinds of imidazole-based curing accelerator may be used.

The insulation resin composition according to the preferred embodiment of the present invention may be prepared as a dry film in a semi solid state by using any general methods known in the art. For example, the insulation resin composition is prepared as a film by using a roll coater, a curtain coater, a comma coater, or the like, and dried. Then, the manufactured film is applied on a substrate to be used as the insulating layer (or an insulating film) or the prepreg at the time of manufacturing a multilayer printed board by a build-up scheme. The above-manufactured insulating film or prepreg increases thermal conductivity and improves relative permittivity and breakdown voltage.

As described above, the insulation resin composition according to the preferred embodiment of the present invention is impregnated into a substrate such as the organic fiber or the inorganic fiber and then cured to manufacture the prepreg, and a copper clad is stacked thereon to obtain a copper clad laminate (CCL). In addition, the insulating film manufactured from the insulation resin composition according to the preferred embodiment of the present invention is laminated on the CCL used as an inner layer at the time of manufacturing the multilayer printed circuit board to be used in manufacturing the multilayer printed circuit board. For example, after the insulating film manufactured from the insulation resin composition is laminated on an inner circuit board having processed patterns formed thereon and cured at a temperature of 80 to 110° C. for 20 to 30 minutes, a dismear process is performed, and a circuit layer is formed through an electroplating process, thereby manufacturing the multilayer printed circuit board.

The inorganic fiber is a glass fiber, and the organic fiber may be used by using one kind or a combination of two or more kinds of a carbon fiber, a polyparaphenylene benzobisoxazol fiber, a thermotropic liquid crystal polymer fiber, a lithotropic liquid crystal polymer fiber, an aramid fiber, a polypyridobisimidazole fiber, a polybenzothiazole fiber, and a polyarylate fiber.

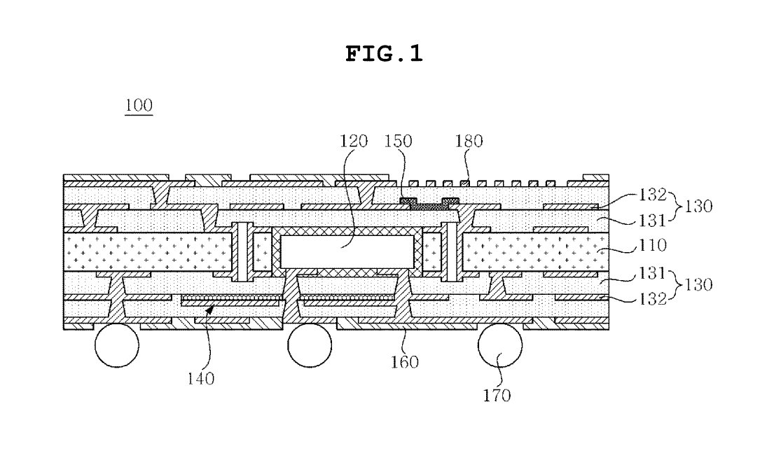

The printed circuit board may be manufactured by using the insulation resin composition according to the preferred embodiment of the present invention, the insulating film or the prepreg using the same. FIG. 1 is a general cross-sectional view showing a printed circuit board manufactured by the above description.

That is, the printed circuit board 100 is largely classified into an insulating layer and a circuit layer, and referring to FIG. 1, the circuit layers 132 are formed on both surfaces of an insulator 110 configuring a core layer, and on the circuit layer, the insulating layer 131 is formed by using a build-up film again, and the circuit layer 132 is formed on the insulating layer 131, thereby configuring a subsequent build-up layer 130. The printed circuit board may include a capacitor 140, a resistor 150, or the other electronic component 120 as needed, and the outermost thereof may be provided with a solder resist layer 160 in order to protect the circuit board. The printed circuit board may be provided with external connection units 170 according to electronic products to be mounted thereon, and sometimes provided with a pad layer 180. The printed circuit board manufactured by the preferred embodiment of the present invention may have improved heat radiation property and significantly excellent mechanical strength.

Hereinafter, the present invention will be described in more detail with reference to the following examples and comparative examples; however, it is not limited thereto.

### EXAMPLE 1

As shown in the following Table 1, 3320.3 g of an o-cresol novolac epoxy resin (YDCN-500-1P, manufactured by Kukdo Chemical Co., Ltd.) and 204.4 g of a dicyandiamide (DICY) curing agent were melted into 2150 g of a methyl ethyl ketone (MEK) solvent to prepare a solution, and 7968.6 g of boron nitride (BN) having an average particle diameter of 7 μm as a first inorganic filler, and 1992.1 g of silica (SiO₂) having an average particle diameter of 0.5 μm as a second inorganic filler were slowly added thereto and mixed by using a mechanical stirrer at 2500 rpm for 1 hour, thereby preparing a resin composition.

### EXAMPLE 2

As shown in the following Table 1, 1992.2 g of an o-cresol novolac epoxy resin (YDCN-500-90P, manufactured by Kukdo Chemical Co., Ltd.) and 204.4 g of a dicyandiamide (DICY) curing agent were melted into 2150 g of a methyl ethyl ketone (MEK) solvent to prepare a solution, and 8015 g of alumina (Al₂O₃) having an average particle diameter of 5 μm as a first inorganic filler, and 3273.8 g of silica (SiO₂) having an average particle diameter of 0.5 μm, as a second inorganic filler were slowly added thereto and mixed by using a mechanical stirrer at 2500 rpm for 1 hour, thereby preparing a resin composition.

### EXAMPLE 3

As shown in the following Table 1, 4359 g of an o-cresol novolac epoxy resin (YDCN-500-90P, manufactured by Kukdo Chemical Co., Ltd.) and 204.4 g of a dicyandiamide (DICY) curing agent were melted into 2150 g of a methyl ethyl ketone (MEK) solvent to prepare a solution, and 8718 g of alumina (Al₂O₃) having an average particle diameter of 15 μm and 6102.6 g of alumina (Al₂O₃) having an average particle diameter of 5 μm as a first inorganic filler, and 2615.4 g of silica (SiO₂) having an average particle diameter of 0.5 μm as a second inorganic filler were slowly added thereto and mixed by using a mechanical stirrer at 2500 rpm for 1 hour, thereby preparing a resin composition.

### COMPARATIVE EXAMPLE 1

As shown in the following Table 1, 4066 g of an o-cresol novolac epoxy resin (YDCN-500-1P, manufactured by Kukdo Chemical Co., Ltd.) and 204.4 g of a dicyandiamide (DICY) curing agent were melted into 2150 g of a methyl ethyl ketone (MEK) solvent to prepare a solution, and 4066.5 g of alumina (Al₂O₃) having an average particle diameter of 5 μm as a first inorganic filler was slowly added thereto and mixed by using a mechanical stirrer at 2500 rpm for 1 hour, thereby preparing a resin composition.

### COMPARATIVE EXAMPLE 2

As shown in the following Table 1, 6506.4 g of an o-cresol novolac epoxy resin (YDCN-500-90P, manufactured by Kukdo Chemical Co., Ltd.) and 204.4 g of a dicyandiamide (DICY) curing agent were melted into 2150 g of a methyl ethyl ketone (MEK) solvent to prepare a solution, and 6506.4 g of alumina (Al₂O₃) having an average particle diameter of 5 μm as a first inorganic filler was slowly added thereto and mixed by using a mechanical stiffer at 2500 rpm for 1 hour, thereby preparing a resin composition.

TABLE 1

| | Epoxy | Curing | | | Dispersant | Defoamer | |
|---|---|---|---|---|---|---|---|
| | Resin | Agent | First | Second | (Disper | (BYK- | Solvent |
| | (YDCN) | (DICY) | Inorganic | Inorganic Filler | BYK- | 066N) | (MEK) |
| | (g) | (g) | Filler (g) | (g) | 180) (g) | (g) | (g) |
| Example 1 | 3320.3 | 204.4 | 7968.6 | 1992.1 | 444.9 | 147.6 | 2150 |
| Example 2 | 1992.2 | 204.4 | 8015 | 3273.8 | 444.9 | 147.6 | 2150 |
| Example 3 | 4359 | 204.4 | 8718 (15 μm) | 2615.4 | 444.9 | 147.6 | 2150 |
| | | | 6102.6 (5 μm) | | | | |
| Comparative | 4066 | 204.4 | 4066.5 | | 444.9 | 147.6 | 2150 |
| Example 1 | | | | | | | |
| Comparative | 6506.4 | 204.4 | 6506.4 | | 444.9 | 147.6 | 2150 |
| Example 2 | | | | | | | |

Manufacture of Insulating Film

### EXAMPLE 1

### In Manufacture of Film

The resin composition prepared in a varnish type of Example 1 above was roll coated on a PET film (having a thickness of 40 μm) and dried at 120° C. for 10 minutes to manufacture an insulating film having a thickness of 85 μm, and the manufactured insulating film was allowed to be separated from the PET film.

### EXAMPLE 2

### In Manufacture of Film

An insulating film having the same condition as Example 1 in manufacture of film above was manufactured by using the resin composition prepared in a varnish type of Example 2 above, and the manufactured insulating film was allowed to be separated from the PET film.

### EXAMPLE 3

### In Manufacture of Film

An insulating film having the same condition as Example 1 in manufacture of film above was manufactured by using the resin composition prepared in a varnish type of Example 3 above, and the manufactured insulating film was allowed to be separated from the PET film.

### COMPARATIVE EXAMPLE 1

### In Manufacture of Film

An insulating film having the same condition as Example 1 in manufacture of film above was manufactured by using the resin composition prepared in a varnish type of Comparative Example 1 above, and the manufactured insulating film was allowed to be separated from the PET film.

### COMPARATIVE EXAMPLE 2

### In Manufacture of Film

An insulating film having the same condition as Example 1 in manufacture of film above was manufactured by using the resin composition prepared in a varnish type of Comparative Example 2 above, and the manufactured insulating film was allowed to be separated from the PET film.

Manufacture of Prepreg

A glass fiber (1078, manufactured by BAOTEK, Inc.) was impregnated using each of the mixture solutions prepared in Examples 1, 2, and 3. The glass fiber having the mixture solution impregnated thereinto was allowed to pass through a heating zone at 200° C. to be semi-cured (B-stage), thereby obtaining a prepreg.

Manufacture of Printed Circuit Board

An inner circuit board in which copper clad layers were stacked on both surfaces thereof was dried at 120° C. for 30 minutes, and then the film manufactured by Examples 1, 2, and 3 were subjected to vacuum lamination on both surfaces thereof under conditions of 90° C. and 2.0 mbar for 20 seconds using a vacuum laminate

Physical properties of the film manufactured by Examples and Comparative Examples in manufacture of film were evaluated and results thereof were shown in the following Table 2. Thermal conductivity was measured by TPA-501 and relative permittivity was measured using an RF impedance analyzer at 1 GHz. In addition, in measuring breakdown voltage, an applied voltage at which the insulating film was broken down was measured by increasing voltage at a rate of 0.5 Kv/sec.

TABLE 2

| | Thermal | | Breakdown |
|---|---|---|---|
| | Conductivity | Relative | Voltage |
| | (W/mK) | Permittivity | (Kv) |
| Example 1 in | 3 | 5.2 | 3.1 |
| Manufacture of Film | | | |
| Example 2 in | 2.9 | 4.7 | 4.0 |
| Manufacture of Film | | | |
| Example 3 in | 4.2 | 5.5 | 3.9 |
| Manufacture of Film | | | |
| Comparative Example | 0.3 | 4.2 | 3.0 |
| 1 in Manufacture of | | | |
| Film | | | |
| Comparative Example | 2.4 | 12.8 | 2.5 |
| 2 in Manufacture of | | | |
| Film | | | |

It could be appreciated from Table 2 above that results regarding thermal conductivity, relative permittivity, and breakdown voltage of Examples 1, 2, and 3 in manufacture of film were more improved as compared to Comparative Examples 1 and 2 in manufacture of film.

The insulation resin composition for a printed circuit board having improved thermal conductivity and electrical properties according to the present invention, the insulating film, the prepreg, and the printed circuit board may have high thermal conductivity, low relative permittivity, and high breakdown voltage.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. An insulation resin composition for a printed circuit board comprising:
an epoxy resin;
a first inorganic filler having thermal conductivity of 20 W/mK or more and an average particle diameter of 1 to 200 μm; and
a second inorganic filler having relative permittivity less than 10 and an average particle diameter of 0.01 to 1 μm.

2. The insulation resin composition for a printed circuit board as set forth in claim 1, wherein the first inorganic filler has an average particle diameter of 1 to 70 μm and the second inorganic filler has an average particle diameter of 0.05 to 1 μm.

3. The insulation resin composition for a printed circuit board as set forth in claim 1, wherein the epoxy resin is at least one selected from a group consisting of a bisphenol A type epoxy resin, a bisphenol F type epoxy resin, a phenol novolac epoxy resin, an o-cresol novolac epoxy resin, a naphthalene-based epoxy resin, a binaphthyl type epoxy resin, an anthracene type epoxy resin, a rubber modified type epoxy resin and a cycloaliphatic type epoxy resin.

4. The insulation resin composition for a printed circuit board as set forth in claim 1, wherein the first inorganic filler is at least one selected from a group consisting of alumina (Al₂O₃), boron nitride (AlN), aluminum nitride (AlN), silicon carbide (SiC), beryllium oxide (BeO), beryllium hydroxide (Be(OH)₂), beryllium carbide (Be₂C) and magnesium oxide (MgO).

5. The insulation resin composition for a printed circuit board as set forth in claim 1, wherein the second inorganic filler is at least one selected from a group consisting of silica (SiO₂), boron nitride (BN), aluminum nitride (AlN), aluminum boride (AlBr₃), and aluminum fluoride (AlF₃).

6. The insulation resin composition for a printed circuit board as set forth in claim 1, wherein the epoxy resin is contained in 5 to 50 wt %, the first inorganic filler is contained in 25 to 85.5 wt %, and the second inorganic filler is contained in 5 to 47.5 wt %.

7. The insulation resin composition for a printed circuit board as set forth in claim 1, further comprising 0.1 to 1 part by weight of at least one curing agent selected from a group consisting of an amine-based curing agent, an acid anhydride-based curing agent, a polyamine curing agent, a polysulfide curing agent, a phenolic novolac type curing agent, a bisphenol A type curing agent and a dicyandiamide curing agent based on 100 parts by weight of the insulation resin composition.

8. The insulation resin composition for a printed circuit board as set forth in claim 1, further comprising 0.01 to 0.1 part by weight of a tertiary amine-based and an imidazole-based curing accelerator based on 100 parts by weight of the insulation resin composition.

9. An insulating film manufactured by coating and semi-curing the insulation resin composition as set forth in claim 1 on a substrate.

10. A prepreg manufactured by impregnating and drying an organic fiber or an inorganic fiber into a varnish containing the insulation resin composition as set forth in claim 1.

11. A printed circuit board manufactured by stacking and laminating the insulating film as set forth in claim 9 on a substrate having circuit patterns formed thereon.

12. A printed circuit board manufactured by stacking and laminating the prepreg as set forth in claim 10 on a substrate having circuit patterns formed thereon.
